(19) United States
(12) Patent Application Publication
(10) Pub. No.: US 2025/0024584 A1
(43) Pub. Date: Jan. 16, 2025

(54) THERMAL INTERFACE ARRANGEMENT

(71) Applicant: GENOMTEC SA, Wroclaw (PL)

(72) Inventor: Henryk Roguszczak, Wroclaw (PL)

(21) Appl. No.: 18/712,728

(22) PCT Filed: Nov. 24, 2022
(86) PCT No.: PCT/EP2022/083183

§ 371 Date: May 23, 2024

(30) Foreign Application Priority Data
Nov. 24, 2021 (GB) 2116943.8

(51) Int. Cl. H05K 1/02; H05K 1/14; H05K 7/20

(52) U.S. Cl. CPC H05K 1/0212; H05K 1/147; H05K 7/20436; H05K 2201/062

(57) ABSTRACT

A thermal interface arrangement for a heater system, the thermal interface arrangement being arranged for establishing a thermal interface with a body to be heated, the arrangement including a support structure and at least one interface assembly mounted on the support structure. The interface assembly includes an interface member arranged to engage the body to form a thermal interface, and at least one biasing member acting between the support structure and the interface member to bias the interface member away from the support structure and into engagement with the body, in use. The biasing member includes thermally insulating material so that the biasing member is configured to resist heat transfer from the interface member to the support structure.

### CROSS-REFERENCE TO RELATED APPLICATIONS

This application is a national stage of, and claims priority to, Patent Cooperation Treaty Application No. PCT/EP2022/083183, filed on Nov. 24, 2022, which claims priority to United Kingdom Application No. GB 2116943.8, filed on Nov. 24, 2021, both of which are hereby incorporated by reference in their entireties.

### FIELD OF THE DISCLOSURE

The disclosure relates to a thermal interface arrangement and to heater systems including such arrangements. In particular, but not exclusively, the disclosure relates to a thermal interface arrangement and associated interface elements for a heater system for heating biological samples in a diagnostic device.

### BACKGROUND TO THE DISCLOSURE

In diagnostic devices that process biological samples, for example point-of-care (PoC) devices configured to detect nucleic acids that are indicative of pathogens, heating of the sample is often required. For example, devices that implement polymerase chain reaction (PCR) processes implement thermal cycling of the sample to amplify genetic material to be detected. Other devices use isothermal techniques, such as loop-mediated isothermal amplification (LAMP), to amplify genetic material by heating the sample at a steady temperature. It is also often necessary to heat the sample to different temperatures at different stages of a test, which typically entails delivering localised heating in multiple locations as the sample is moved through the device during a test procedure.

For accurate and reliable results, heating must be applied with precision and substantially uniformly throughout each sample over successive test procedures. It is also important that the sample is heated efficiently, especially in mobile devices that may be battery-powered.

To avoid contamination of device components, in some arrangements a sample is loaded into a disposable test cartridge that is then docked with the device. The device then processes the sample contained within the cartridge whilst avoiding direct contact with the sample, and once the test completes the cartridge and the sample within can be disposed of. The device can then be used immediately to perform the next test without any cleaning requirement.

Disposable test cartridges may be configured as passive, in the sense of including no electronic components, thereby reducing their cost and enhancing disposability. In such arrangements, the main device includes heating components that are configured to transfer heat to a sample within a docked cartridge. The accuracy, speed and efficiency of heating that is achieved in the sample is dependent on the performance of a thermal interface that is created between the heating components and the test cartridge. Notably, such interfaces are not permanent, but must be established each time a new cartridge is docked with the device. Firm and complete contact at the thermal interface between the cartridge and the heating components must be created in a repeatable and reliable manner, to ensure effective heat transfer to each new cartridge through successive test procedures.

One known solution is to provide each test cartridge with a copper plate on its exterior that acts as a thermal interface plate that can be heated by the main device and, in turn, transfer heat to a sample inside the cartridge. The copper plate may be heated using a non-contact technique, for example using LEDs within the device to irradiate the plate. Due to its high thermal conductivity, the copper plate distributes heat evenly over its interface with the cartridge, in turn achieving substantially uniform heating of the sample.

However, the copper plate represents an additional component in the test cartridge, thus raising the cost of the cartridge. Moreover, the copper plate must be securely attached to the cartridge housing, typically using adhesive, to create the required thermal interface, which adds a manufacturing step and therefore additional cost.

It is against this background that the present disclosure has been devised.

### SUMMARY OF THE DISCLOSURE

An aspect of the disclosure provides an interface element for a heater system, for example a heater system of a diagnostic device. The interface element is arranged for establishing a thermal interface with a body to be heated by the heater system. The element comprises an interface member arranged to engage the body. The interface member comprises a thermally conductive layer that is supported by a rigid substrate layer, the thermally conductive layer covering at least a majority of a surface area of the rigid substrate layer. The interface element further comprises at least one flexible biasing member, and optionally a set of such biasing members, connected to and extending from the interface member. The, or each, biasing member is arranged to bias the interface member into engagement with the body, in use. The, or each, biasing member comprises thermally insulating material, so that the biasing member is configured to resist heat transfer away from the interface member.

The substrate layer may be disposed between a pair of conductive layers, in which case the interface member may comprise thermal links extending between the conductive layers, such as thermal vias.

The interface member may comprise a rigid substrate layer and a flexible substrate layer. In such embodiments, the biasing member may be formed from the same material as the flexible substrate layer of the interface member, and may be continuous with the flexible substrate layer.

The, or each, conductive layer is optionally divided into multiple thermally conductive regions separated by thermally insulating regions. This may allow each region to be heated to a different temperature, for example.

The interface element may comprise an electrically conductive path extending along the length of the biasing member and onto the interface member. Such paths may allow electrical power to be delivered to components mounted on or in the interface member, such as a temperature sensor.

Conveniently, the interface element may be formed as a flexi-rigid printed circuit board. Accordingly, the interface element may be fabricated by a printed circuit board (PCB) manufacturer using conventional materials and processes.

A set of biasing members may be arranged around the interface member. The biasing members may be evenly spaced around the interface member, and may be substantially orthogonal to an edge of the interface member, or a tangent of the edge, from which the biasing member extends.

The interface element may comprise at least one axis of symmetry and/or at least one degree of rotational symmetry. Each axis or degree of symmetry may extend through a respective biasing member, for example. The interface element may have a respective axis and/or degree of symmetry for each biasing member.

Another aspect of the disclosure provides a thermal interface arrangement for a heater system, for example a heater system of a diagnostic device. The thermal interface arrangement is arranged for establishing a thermal interface with a body to be heated by the heater system. The arrangement comprises a support structure, and an interface assembly mounted on the support structure. The interface assembly comprises an interface member arranged to engage the body to form a thermal interface, and a biasing member acting between the support structure and the interface member to bias the interface member away from the support structure and into engagement with the body, in use. The biasing member comprises thermally insulating material so that the biasing member is configured to resist heat transfer from the interface member to the support structure.

The interface assembly of the thermal interface arrangement may be defined by an interface element, for example the interface element of the above aspect.

For the above thermal interface arrangement or interface element, thermally insulating material may represent at least half of the volume of the, or each, biasing member. The, or each, biasing member may be formed predominantly from thermally insulating material.

The, or each, biasing member may be formed integrally with the interface member.

The interface member is optionally divided into multiple heating zones separated by thermally insulating material, which may enable the heating zones to be heated to different temperatures. This may be useful where those zones are in contact with areas of the body that correspond to different stages of a test procedure where different heating regimes are required, for example.

The thermal interface arrangement may comprise a temperature sensor configured to generate a signal indicative of a temperature of the interface member, for example a PT100 or PT1000. The temperature sensor may be attached to the interface member, in which case the biasing member comprises an electrically conductive path that is connected to the temperature sensor and extends to the support structure.

The support structure may comprise a circuit board.

The thermal interface arrangement may comprise multiple interface assemblies mounted on the support structure.

The interface assembly may comprise multiple biasing members acting between the support structure and the interface member. The biasing members of an interface assembly may be of substantially equal length. The biasing members may be evenly spaced around the interface member, and may be substantially orthogonal to an edge of the interface member, or a tangent of the edge, from which the biasing member extends.

In some embodiments, the interface member comprises thermally conductive material, which may cover at least a majority of a surface area of the interface member. The interface member of an interface assembly may comprise a thermally conductive layer that is supported by a rigid substrate layer, the thermally conductive layer covering at least a majority of a surface area of the rigid substrate layer. The substrate layer may be disposed between a pair of conductive layers, in which case the interface member may comprise thermal links extending between the conductive layers. The interface member optionally comprises a rigid substrate layer and a flexible substrate layer. The biasing member may be formed from the same material as the flexible substrate layer of the interface member. The biasing member may be continuous with the flexible substrate layer of the interface member. The or each interface assembly may be formed as a flexi-rigid printed circuit board.

The, or each, interface assembly may comprise at least one axis of symmetry and/or at least one degree of rotational symmetry.

In the above interface element or thermal interface arrangement, the biasing members may be of substantially equal length. The biasing members may also be of equal width and thickness. This helps to ensure that the biasing members generate similar spring forces, when compressed, to bias the interface member in a balanced manner.

The interface member of an interface element or an interface assembly may comprise an absorption layer that is configured to absorb photon energy to generate heat when the interface member is irradiated by a light source.

The disclosure also extends to a heater system comprising the thermal interface arrangement of the above aspect and a heater arrangement configured to heat the interface member.

The heater arrangement may be integrated with the thermal interface arrangement.

The heater arrangement may comprise a light source that is operable to direct radiation towards the interface member. The light source may be mounted on the support structure of the thermal interface arrangement. The light source may comprise a light emitting diode. The light source may be arranged to emit radiation in the ultraviolet and/or visible range. Such radiation can then be absorbed by the interface member, or by a coating covering a surface of the interface member, and converted to heat to be transferred to the body. Relative to using radiation in the infrared range, the use of radiation in the visible and/or ultraviolet region may be more efficient electrically, and may allow contactless temperature sensing in the infrared range, for example using a pyrometer.

The heater arrangement may comprise a heater mounted on, or integral with, the interface member.

If the thermal interface arrangement includes multiple interface members, the heater arrangement may be configured to heat each interface member. The heater arrangement may be configured to heat each interface member independently, for example to heat each interface member to a different temperature and/or at different heating powers.

The disclosure further extends to a diagnostic device comprising the interface element, the thermal interface arrangement, or the heater system of the above aspects.

In the above aspects of the disclosure, biasing the interface member into engagement with the body helps to establish a strong thermal interface through which heat may be transferred to the body. The thermally insulating material of the, or each, biasing member resists heat transfer through the biasing member, and therefore minimises the extent to which the biasing member creates a thermal bridge that carries heat away from the interface member to any structure that the biasing member may be in contact with, such as the support structure of the above thermal interface arrangement. Accordingly, the interface element or interface assembly is configured to maximise the proportion of heat that is transferred to the body.

It will be appreciated that preferred and/or optional features of each aspect of the disclosure may be incorporated alone or in appropriate combination in the other aspects of the disclosure also.

### BRIEF DESCRIPTION OF THE DRAWINGS

In order that the disclosure may be more readily understood, preferred non-limiting embodiments thereof will now be described, by way of example only, with reference to the accompanying drawings, in which like features are assigned like reference numerals, and in which:

FIG. 1 is a perspective view of a heater assembly according to an embodiment of the disclosure;

FIG. 2 shows the heater assembly of FIG. 1 in plan view;

FIG. 3 shows the heater assembly of FIG. 1 in a side perspective view;

FIG. 4 shows the heater assembly of FIG. 1 in a diagnostic device;

FIG. 5 shows a flat pattern for an interface element of the heater assembly of FIG. 1;

FIG. 6 shows a cross-sectional view of an interface plate of the heater assembly of FIG. 1;

FIG. 7 is a perspective view of a heater assembly according to another embodiment of the disclosure;

FIG. 8 shows the heater assembly of FIG. 7 in plan view; and

FIG. 9 shows a flat pattern for an interface element of the heater assembly of FIG. 7.

### DETAILED DESCRIPTION OF EMBODIMENTS OF THE DISCLOSURE

In general terms, embodiments of the disclosure provide thermal interface arrangements configured to create a temporary high-performance thermal interface with a body to be heated using an interface member that is biased into engagement with the body. Embodiments of the disclosure also provide heater systems comprising such thermal interface arrangements in combination with a heater arrangement capable of heating the interface member, and thus heating the body via the thermal interface.

In the embodiments described below, the body to be heated is a test cartridge for a diagnostic device, the test cartridge containing a biological sample that is heated as part of a test procedure. It should be appreciated, however, that thermal interface arrangements and heater systems of the disclosure may be used in a range of other applications to heat bodies and housings of various kinds, and in general terms may be useful in any context in which a surface of a body must be heated.

In embodiments of the disclosure, one or more interface members in the form of interface plates are biased into contact with a surface of the body that is to be heated by one or more resilient biasing members. Each interface plate and its associated biasing members form an interface assembly that is used to create a temporary thermal interface with the body to be heated in a reliable and repeatable manner. The interface assembly may therefore be considered to act as a heating assembly.

Biasing the interface plate into contact with the body improves thermal contact between the interface plate and the body, thereby enhancing the thermal interface without having to secure the plate to the body permanently using adhesive or mechanical fixings. When used in the context of a diagnostic device, the interface plate can replace the copper plate noted about that is used for transferring heat into the cartridge. As the interface plate is not attached to the test cartridge, it can become part of the main device to be reused with successive test cartridges. Correspondingly, the cartridge can be simplified and so become more disposable by removing the copper plate.

The biasing members comprise thermally insulating material, and may be predominantly composed of such material, and so are configured to avoid creating thermal bridges between the interface plate and a support structure to which the plate is attached. Such thermal bridges would otherwise undermine the performance of the heater assembly, by allowing heat to conduct from the interface plate to the support structure, thereby reducing heating efficiency.

In some embodiments, a set of biasing members are evenly distributed around the edge of the interface plate, which ensures that biasing force is balanced across the interface plate so that the surface of the interface plate is held is firm contact with the surface of the test cartridge or other housing.

Advantageously, an interface assembly may be configured as an interface element in which one or more biasing members are formed integrally with the interface plate. For example, an interface element may have resilient legs defining biasing members extending from an interface plate. In embodiments to be described, such interface elements may be formed in the manner of flexi-rigid printed circuit boards (PCBs), albeit with substantially continuous conductive layers instead of the usual network of conductive traces defining electrical circuits in a PCB. Conveniently, such interface elements can be produced using conventional PCB fabrication techniques, where the legs are formed from flexible substrate material while the interface plate is rigid and includes conductive layers of copper on each side that act as effective thermal conductors.

Alternatively, it is also possible to form an interface assembly by connecting one or more biasing members to an interface plate or other interface member using any suitable connection technique, so that the biasing members are not integral with the interface plate.

Typically, the mass of the interface plate is small such that the interface plate has low thermal inertia. This ensures that thermal energy does not accumulate in the interface plate, and so transfers quickly to the body. The low thermal mass therefore accelerates heating of the body, and in turn allows for rapid cooling when heating power is deactivated, thereby greatly enhancing the ability to control the temperature of the body.

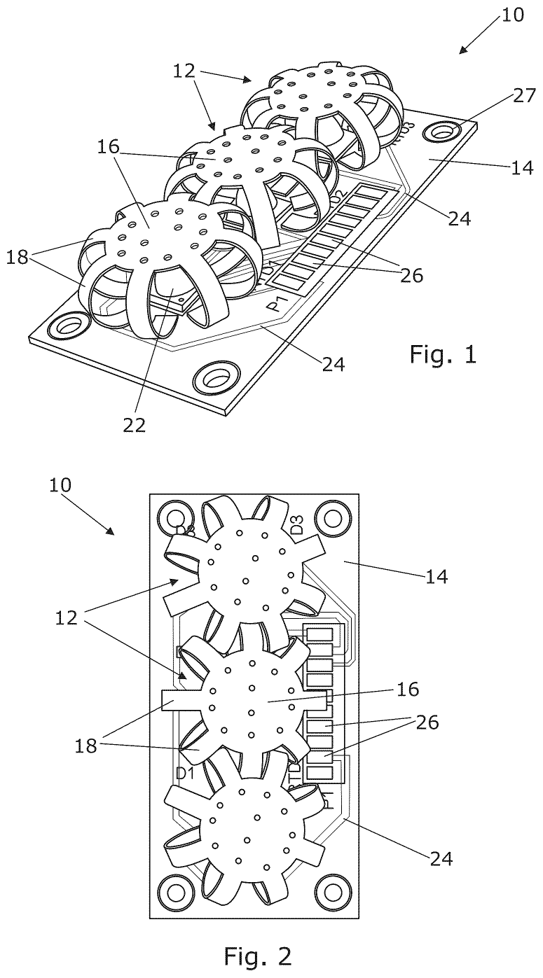

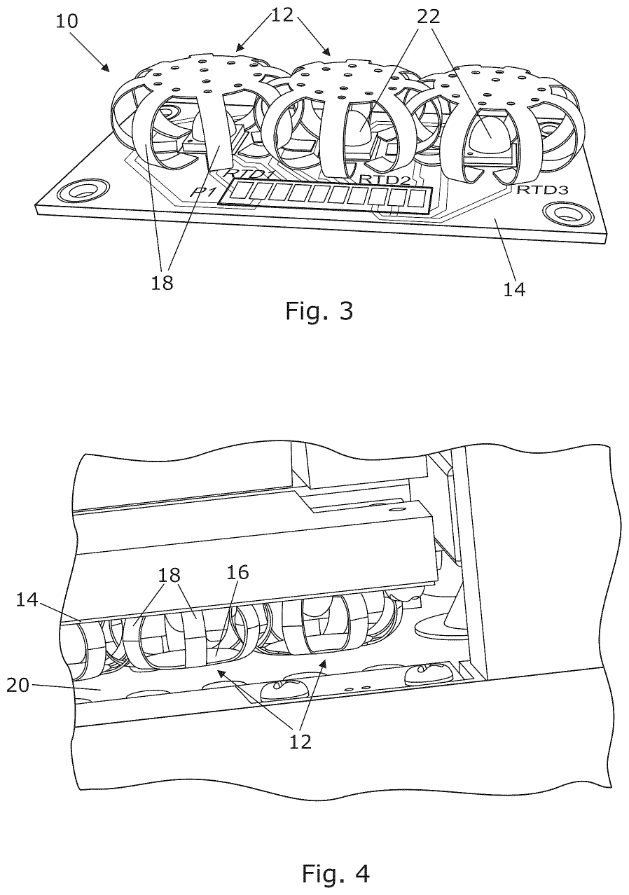

Referring now to FIGS. 1 to 3, a heater system or heater assembly 10 according to an embodiment of the disclosure is shown. The heater assembly 10 is configured for use in a diagnostic device to heat biological samples held in a test cartridge docked with the device for processing, and is shown in this context in FIG. 4.

The heater assembly 10 includes three interface elements 12 mounted in linear series on a PCB defining a control board 14. The control board 14 acts as a support structure for the interface elements 12, such that the control board 14 and the interface elements 12 collectively define a thermal interface arrangement that is configured to form thermal interfaces with a test cartridge.

The support structure also supports components of a heater arrangement of the heater assembly 10, the heater arrangement being configured to heat the interface elements 12. Accordingly, the heater assembly 10 integrates the thermal interface arrangement with the heater arrangement, and so is configured both to form thermal interfaces with the test cartridge and to deliver heating power to those interfaces. In other embodiments, however, the thermal interface arrangement may be separate from the heater arrangement. Conversely, the thermal interface arrangement may include an integral heater arrangement, as described later.

Each interface element 12 comprises a planar, circular interface plate 16 from which an array of eight identical, elongate, equi-spaced legs 18 extend radially outwardly. Each interface plate 16 has an underside that faces the control board 14, and an outwardly-directed face that defines an engagement face that engages the surface of a test cartridge, in use.

The respective interface plates 16 of the interface elements 12 are arranged to engage a different part of a test cartridge housing, to form thermal interfaces with the test cartridge and thereby apply localised heating during a test procedure. The interface elements 12 may therefore be considered to act as heating elements. For example, each interface plate 16 may align with a respective well within the test cartridge, when engaged, to heat sample fluid held within the well in operation. The test cartridge may include recesses in which the interface plates 16 locate as they engage the cartridge, to ensure correct alignment.

Each interface plate 16 has a diameter of approximately 8 mm in this embodiment. This may generally correspond to the size of wells with which the interface plates 16 align, such that each interface plate 16 transfers heat to its entire corresponding well uniformly. The interface plate 16 locates approximately 6 mm above the control board 14 when at rest.

In use, the interface plates 16 are heated to transfer heat to the parts of the test cartridge that they are in contact with. Accordingly, in this embodiment the exterior surfaces of the interface plates 16 are formed from thermally conductive material, for example copper, to facilitate effective and uniform heating at the interfaces with the test cartridge. The interface plates 16 are rigid to resist deformation when pressed into engagement with a test cartridge, enabling uniform contact over the interface with the cartridge and therefore promoting uniform heat transfer over the thermal interface defined by the contact area.

As best seen in FIG. 1, each leg 18 is resilient and is bent along its length to form a semi-circular arc beneath its respective interface plate 16. Each leg 18 extends from the interface plate 16 at a proximal end to the control board 14 at a distal end. Accordingly, the interface element 12 is generally spider-like in form. Each leg 18 is fixed to the control board 14 at its distal end by soldering in this example, although any suitable means of attachment may be used, including adhesive or mechanical fixings, for example. The legs 18 are formed integrally with the interface plate 16 in this embodiment.

The legs 18 comprise thermally insulating material, and in this embodiment are predominantly formed from such insulating material, so that they do not create thermal bridges between the interface plate 16 and the control board 14 when the interface plate 16 is heated. In this way, the legs 18 create a degree of thermal isolation between the interface plates 16 and the control board 14, in turn maximising the proportion of heat generated in the interface plate 16 that is transferred into an engaged test cartridge. In contrast, if metal springs were used as biasing members the efficiency of the assembly would reduce significantly.

The legs 18 of each interface element 12 also act collectively to bias the respective interface plate 16 away from the control board 14. Accordingly, if an interface plate 16 is pressed towards the control board 14, the associated legs 18 generate an opposing spring force that acts to return the interface plate 16 to the rest position shown in FIGS. 1 to 3. The even spacing of the legs 18 around the edge of the interface plate 16 creates a correspondingly balanced biasing force, which maintains the correct orientation of the interface plate 16 and ensures that all parts of the interface plate 16 are pressed into engagement with the test cartridge.

FIG. 4 shows the heater assembly 10 in context within the device, with the interface elements 12 engaged with a test cartridge 20 that is docked within the device beneath the heater assembly 10. As is evident from the increased deformation of the legs 18 of the interface elements 12 relative to the rest position shown in FIGS. 1 to 3, the device is configured such that the test cartridge 20, when docked, is closer to the control board 14 than the interface plates 16 are when in the rest position, so that the interface elements 12 are compressed between the control board 14 and the cartridge 20. Specifically, in this embodiment a 4 mm gap exists between the test cartridge 20 and the control board 14 when the cartridge 20 is docked. Since the interface elements 12 sit 6 mm above the control board 14 at rest, a 2 mm deflection of the interface elements 12 arises when the cartridge 20 is moved into place.

Accordingly, as a test cartridge 20 is moved into position within the device, the cartridge 20 urges the interface plates 16 towards the control board 14, in doing so bending the legs 18 further. In response, the legs 18 generate a spring force that presses the interface plates 16 against the surface of the test cartridge 20, thus forming firm contact and, in turn, robust thermal interfaces, between the engagement faces of the interface plates 16 and the surface of the test cartridge 20. In this embodiment, the 2 mm deflection of each interface plate 16 as the test cartridge 20 moves into place creates a spring force equivalent to 30 grams, the spring force being proportional to the deflection of the interface plate 16.

Returning to FIGS. 1 to 3, beneath each interface element 12 the control board 14 includes a light source in the form of a surface-mounted light-emitting diode (LED) 22, each LED 22 being aligned with the centre of the respective interface plate 16. The LED 22 forms part of the heater arrangement that heats the associated interface plate 16, in use.

In this embodiment, each LED 22 is configured to emit radiation in the ultraviolet and/or visible range, and to direct that radiation towards the underside of its respective interface plate 16. Each interface plate 16 is configured to generate heat, when irradiated, through spectral conversion that converts the energy carried by photons in the radiation into heat. For example, the underside of the interface plate 16 may be coated with a material forming an absorption layer that performs the required conversion, suitable materials including aluminium oxides or modified polymers such as carbon or graphene. The absorption layer may alternatively, or additionally, be substantially black in colour to provide the required absorption behaviour.

The control board 14 includes surface tracks 24 and an array of contact points 26 providing a network of electrical connections. This network includes connections between some of the contact points 26 and each of the LEDs 22, enabling the device to supply electrical power to the LEDs 22 via the relevant contact points 26, in operation. Further connections relate to temperature sensors embedded within each of the interface plates 16, as described in more detail below, enabling feedback loop control of the temperature of each interface plate 16 for precise heating of the test cartridge 20. Such control is implemented by a main controller of the device (not shown).

The control board 14 also includes a mounting hole 27 at each corner, providing for mounting of the heater assembly 10 within the device.

Accordingly, the heater assembly 10 is configured to heat each interface plate 16 in a non-contact manner. Whilst it is also possible to heat the interface plates 16 directly, for example using resistive heaters mounted directly onto the interface plates 16, this would entail providing electrically conductive paths between the control board 14 and the interface plates 16 to deliver electrical power to the heaters. For example, the heater could be defined by one or more copper tracks etched onto the surface of the interface plate 16, and electrical power could be delivered to the heater through copper tracks extending through legs 18 of an interface member. Such tracks would need to be relatively large due to the power consumption of a heater. Accordingly, such paths would create significant thermal bridges through which heat generated in the interface plates 16 would conduct back to the control board 14 and therefore reduce the heating power delivered to the test cartridge 20. So, heating the interface plates 16 in a non-contact manner increases the heating power that is transferred to the test cartridge 20 and thus enhances the efficiency of the device.

Another possible alternative is to use LEDs that emit infrared radiation to heat the interface plates 16, thereby avoiding the need to convert the radiation into heat as in the present embodiment. However, the use of LEDs that operate in the ultraviolet and/or visible range, as in the present embodiment, beneficially offers enhanced efficiency relative to infrared LEDs, and also allows for simultaneous non-contact temperature sensing using, for example, a pyrometer, as the heating and sensing functions are performed using radiation in different frequency ranges.

As each interface plate 16 is heated using a separate LED 22, the interface plates 16 can be heated independently of one another. This allows each interface plate 16 to be heated to a different temperature, for example, which may be useful in devices implementing processes requiring successive heating stages for the sample at differing temperatures.

In this embodiment, each interface element 12 is formed in the manner of a flexi-rigid PCB, albeit having substantially continuous conductive layers instead of electrical circuits, in which the legs 18 are integral with the interface plate 16. The legs 18 therefore may be considered to represent flexible portions of the PCB and are formed from flexible substrate material, while the interface plate 16 represents a rigid portion of the PCB and so includes rigid substrate material. In general terms, the interface elements 12 can be produced by supplying the relevant design parameters to PCB manufacturers in the conventional way. This provides a convenient means for fabricating the interface elements 12 using readily available processes and materials.

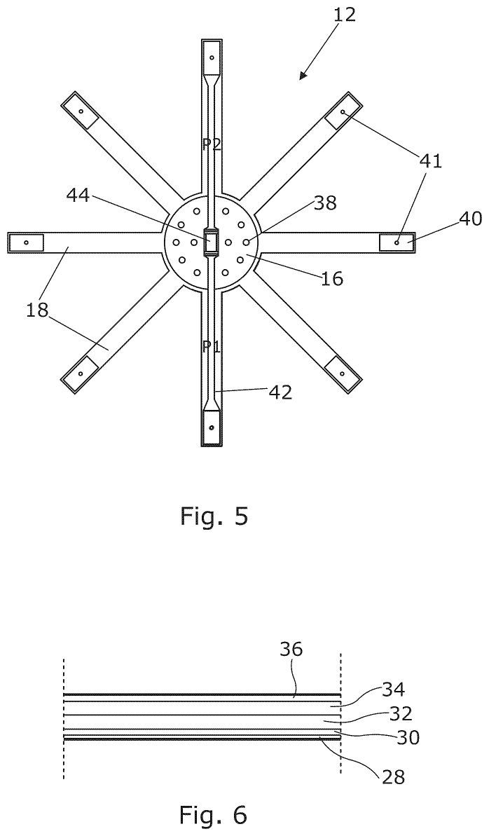

In this respect, FIG. 5 shows the interface element 12 in an unassembled initial state defining a flat pattern, which represents the product that would be supplied by a PCB manufacturer. The flat pattern includes a central circular disc portion that will become the interface plate 16, from which a circular array of oblong portions that will become the legs 18 extend radially. The legs 18 can be bent into the shape shown in FIGS. 1 to 3 to assemble the interface element 12 on the control board 14. FIG. 5 makes clear that the profile of the interface element 12 has eight degrees of rotational symmetry and eight axes of symmetry intersecting at a centre of the interface plate 16.

In this embodiment, the interface element 12 has a single continuous flexible substrate having the shape shown in FIG. 5, such that the flexible substrate layer extends through all parts of the interface element 12. Various materials are used for flexible substrates in PCBs, such as polyimide for example, any of which are suitable for use in embodiments of the disclosure. The flexible substrate has a thickness of 0.15 mm in this embodiment, which therefore corresponds to the thickness of the legs 18. It is noted that the flexible substrate may be composed of multiple laminated FPC layers and may also include coverlays, as is conventional.

The interface plate 16 also includes a rigid substrate layer that is bonded onto the flexible substrate to confer rigidity to the interface plate 16. The rigid substrate layer may be of any suitable rigid non-conductive material, for example FR-4 glass-reinforced epoxy, or ceramics including alumina, aluminium nitride and beryllium oxide.

While the substrate materials used in PCBs are selected on the basis of being non-conductive in terms of electrical conductivity, advantageously such materials also typically have low thermal conductivity and thus may be considered thermally insulating materials for the purposes of the heater assembly 10.

The substrate layers of the interface plate 16 are sandwiched between conductive layers of copper to form a laminate. In this respect, FIG. 6 illustratively shows a cross-section of the interface plate 16, revealing the layers forming the plate 16. In upward succession, these layers include: the absorption layer 28; a lower conductive layer 30; a flexible substrate layer 32; a rigid substrate layer 34; and an upper conductive layer 36. Further substrate layers may also be included between the conductive layers 30, 36. The upper and lower conductive layers 30, 36 are therefore separated by the substrate layers 32, 34 and define the main exterior surfaces of the laminate, notwithstanding any coatings that may be applied, including the absorption layer 28 and protective coatings such as thermally conductive resin that adds stiffness to the structure and creates a smooth, flat surface for the interface plate 16.

Whilst copper layers are conventionally etched to form the required circuits in a PCB, in this embodiment the conductive layers 30, 36 are left substantially intact to cover the majority of the surfaces of the interface plate 16. The conductive layers 30, 36 typically cover the surfaces of the interface plate 16 as fully as possible. For example, the conductive layers 30, 36 cover at least half, typically over 75%, and preferably over 80% of the exterior surfaces of the interface plate 16. When space occupied by any sensors present and the vias described below is taken into account, up to 95% coverage or more may be achievable. The extent of coverage of the conductive layers 30, 36 will be determined in accordance with the needs of each application, taking into account the constraints of the manufacturing process.

The thickness of each conductive layer 30, 36 is approximately 70 microns in this embodiment. The copper material of the conductive layers 30, 36 may optionally have a gold coating of a thickness of 1U, 2U or 3U, for example.

The interface plate 16 is penetrated by several through-holes that are distributed evenly over the interface plate 16, the interiors of the holes being plated with copper or another thermally conductive material. The holes define thermal vias 38 that extend between the upper and lower conductive layers 30, 36 to form thermal links that transfer heat between the conductive layers 30, 36, in use.

The regions of the interface element 12 defining the legs 18 are free of rigid substrate and are formed almost entirely from the flexible substrate layer 32. Each leg 18 is therefore predominantly composed of the thermally insulating material used for the flexible substrate layer 32. The legs 18 are therefore also resilient, being composed of flexible material.

As shown in FIG. 5, rectangular patches 40 of conductive material, for example copper, are included at the distal end of each leg 18. These patches 40 enable the legs 18 to be soldered to the control board 14. The patches 40 are separated from the conductive material of the associated interface plate 16, and so do not contribute significantly to heat transfer through the legs 18. FIG. 5 shows central holes 41 in each of the patches, which aid locating of the patches 40 on the control board 14 during assembly, for example using a temporary rivet.

FIG. 5 also shows that the interface element 12 includes a trace 42 of conductive material, again typically copper, that extends through the centre of the interface plate 16 and centrally along two of the legs 18 that are positioned diametrically opposite one another across the interface plate 16. The trace 42 connects the respective patches of the legs 18 and also connects to a temperature sensor 44 that is mounted to the interface plate 16, for example a PT1000.

While the trace 42 creates a thermally conductive path through the legs 18, this may be acceptable as the power requirements of the sensor 44 are low and so the trace 42 can be small, thereby minimising heat transfer through the trace 42. In particular, the size of the trace 42 required for the sensor 44 is significantly smaller than that required for a heater, and so incorporating the sensor 44 in the interface plate 16 does not create a significant thermal bridge between the plate 16 and the control board 14 in the way that incorporating a heater would.

Accordingly, signals indicative of the temperature of the interface plate 16 that are generated by the temperature sensor 44, in use, can be transmitted to the main controller of the device via the trace 42 and the connections provided on the control board 14. The device controller then controls operation of the associated LED 22 in response to the temperature signals received from the sensor 44, to control the temperature of the interface plate 16 to a target value.

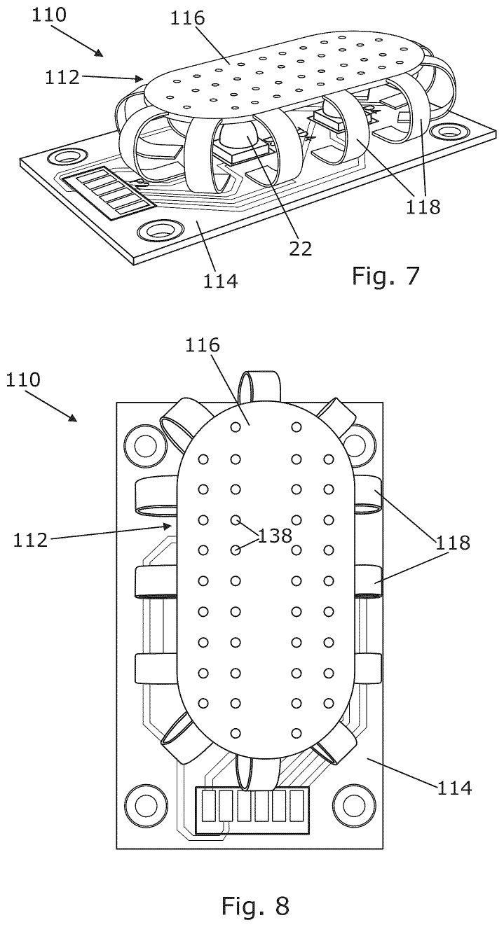

FIGS. 7 and 8 show an alternative heater assembly 110 representing a second embodiment of the disclosure, in which the three interface elements 12 of the first embodiment shown in FIGS. 1 to 6 are replaced by a single, larger interface element 112.

As in the first embodiment, the interface element 112 of FIGS. 7 and 8 has an interface plate 116 supported on a control board 114 by a set of legs 118 distributed around the edge of the plate 116. The interface plate 116 is oblong with rounded corners, and is sized to cover the entire area occupied by the three interface plates 16 of the first embodiment collectively.

As in the first embodiment, the legs 118 are of substantially equal length and width. Accordingly, the legs 118 are bent into similarly shaped arcs—and thus generate similar spring forces—when the interface element 112 is mounted to the control board 114. In this way, the biasing forces provided by the legs 118 are balanced around the interface plate 116.

Each leg 118 extends orthogonally to the edge of the interface plate 116 from which it extends or, where the edge is curved, a tangent to that edge. Orienting the legs 118 in this manner avoids twisting of the leg 18 when it is bent underneath the interface plate 116.

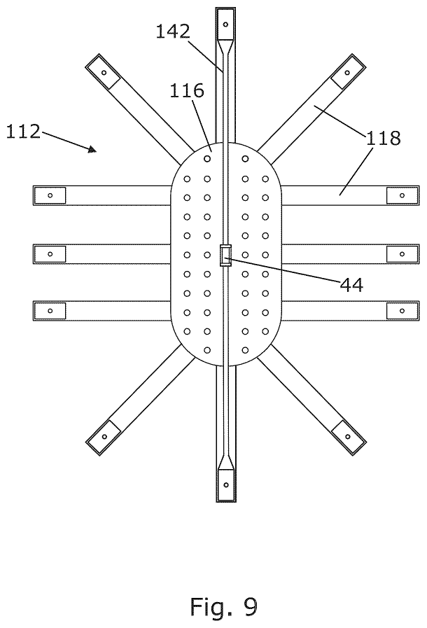

As for the first embodiment, the interface element 112 shown in FIGS. 7 and 8 is fabricated in the manner of a flexi-rigid PCB. In this respect, FIG. 9 shows a flat pattern that represents the product that would be delivered by a PCB manufacturer, whose legs 118 can be bent into shape and attached to a control board 114 as shown in FIGS. 7 and 8. FIG. 9 also makes clear that the profile of the interface element 112 of FIGS. 7 and 8 has two degrees of rotational symmetry, as well as two orthogonal axes of symmetry intersecting at a centre of the interface plate 116.

It follows that the interface plate 116 has a similar structure to that of the first embodiment, as shown in FIG. 6. Also, the interface plate 116 again includes an array of thermal vias 138 that connect the upper and lower conductive layers to minimise thermal resistance between the upper and lower surfaces of the interface plate 116.

In the simplest implementation, the interface plate 116 has continuous conductive surfaces on each side and so is heated as a whole to a uniform temperature, in turn heating a corresponding part of an engaged test cartridge 20 to a single temperature. The control board 114 includes a pair of LEDs 22 that act in tandem to heat the interface plate 116, the LEDs 22 being spaced to aid distribution of heat generated in the interface plate 116 to promote uniform heating of the test cartridge 20. FIG. 9 also shows a conductive trace 142 extending through an aligned pair of legs to connect to a temperature sensor 44 mounted on the interface plate 116.

However, in the embodiment shown in FIGS. 7 and 8, dashed lines represent a discontinuity formed in the conductive layer of the interface plate 116, with a corresponding discontinuity being formed on the opposite side of the interface plate 116 that is not visible in FIG. 8. Each discontinuity may be formed by removing a strip of conductive material from the conductive layer, for example by etching. The discontinuities divide the interface plate 116 into two distinct heating zones that are isolated from each other, each of which can be irradiated separately by a respective one of the LEDs 22. Each heating zone may also be provided with a respective temperature sensor. Accordingly, each heating zone can be heated independently of the other, optionally to different temperatures, by the LEDs 22.

It will be appreciated by a person skilled in the art that the disclosure could be modified to take many alternative forms to that described herein, without departing from the scope of the appended claims.

For example, the interface elements may not be fabricated as PCBs, and various other manufacturing options are possible to create elements having thermally insulating, flexible legs that support a rigid, thermally conductive interface plate.

Although mounting the LEDs on the same support structure as the interface elements provides a compact arrangement, in other embodiments the LEDs may be mounted separately from the interface elements. Accordingly, and in general terms, the interface elements and the thermal interface arrangement may be separate from heating components that heat a body with which the thermal interface arrangement establishes a thermal interface. The interface arrangement may nonetheless be considered to form part of an overall heating system in such arrangements, to the extent that the body is heated via the interface arrangement. It follows that thermal interface arrangements may be retrofitted to existing heating systems to improve heat transfer to a body to be heated.

1. A thermal interface arrangement for a heater system, the thermal interface arrangement being arranged for establishing a thermal interface with a body to be heated, the arrangement comprising:
a support structure; and
an interface assembly mounted on the support structure, the interface assembly including:
an interface member arranged to engage the body to form a thermal interface; and
a biasing member acting between the support structure and the interface member to bias the interface member away from the support structure and into engagement with the body, in use, wherein the biasing member includes thermally insulating material so that the biasing member is configured to resist heat transfer from the interface member to the support structure.

2. The thermal interface arrangement of claim 1, wherein the biasing member is formed integrally with the interface member.

3. The thermal interface arrangement of claim 1, wherein the interface member is divided into multiple heating zones separated by thermally insulating material.

4. The thermal interface arrangement of claim 1, comprising a temperature sensor configured to generate a signal indicative of a temperature of the interface member.

5. The thermal interface arrangement of claim 4, wherein the temperature sensor is attached to the interface member, and the biasing member comprises an electrically conductive path that is connected to the temperature sensor and extends to the support structure.

6. The thermal interface arrangement of claim 1, wherein the support structure includes a circuit board.

7. The thermal interface arrangement of claim 1, wherein the interface member includes a thermally conductive layer that is supported by a rigid substrate layer, the thermally conductive layer covering at least a majority of a surface area of the rigid substrate layer.

8. The thermal interface arrangement of claim 7, wherein the substrate layer is disposed between a pair of conductive layers.

9. The thermal interface arrangement of claim 8, wherein the interface member includes thermal links extending between the conductive layers.

10. The thermal interface arrangement of claim 7, wherein the interface member includes a rigid substrate layer and a flexible substrate layer.

11. The thermal interface arrangement of claim 10, wherein the biasing member is formed from the same material as the flexible substrate layer of the interface member.

12. The thermal interface arrangement of claim 11, wherein the biasing member is continuous with the flexible substrate layer of the interface member.

13. The thermal interface arrangement of claim 7, wherein the interface assembly is formed as a flexi-rigid printed circuit board.

14. The thermal interface arrangement of claim 1, wherein the interface assembly includes at least one axis of symmetry and/or at least one degree of rotational symmetry.

15. The thermal interface arrangement of claim 1, wherein thermally insulating material represents at least half of the volume of the biasing member.

16. The thermal interface arrangement of claim 15, wherein the biasing member is formed predominantly from thermally insulating material.

17. The thermal interface arrangement of claim 1, wherein the interface member includes an absorption layer that is configured to absorb photon energy to generate heat when the interface member is irradiated by a light source.

18. The thermal interface arrangement of claim 1, further comprising multiple interface assemblies mounted on the support structure.

19. The thermal interface arrangement of claim 1, wherein the interface assembly includes multiple biasing members acting between the support structure and the interface member.

20. The thermal interface arrangement of claim 19, wherein the biasing members are of substantially equal length.

21. An interface element for a heater system, the interface element being arranged for establishing a thermal interface with a body to be heated, the element comprising:
an interface member arranged to engage the body, the interface member including a thermally conductive layer that is supported by a rigid substrate layer, the thermally conductive layer covering at least a majority of a surface area of the rigid substrate layer; and
at least one flexible biasing member extending from the interface member, the biasing member being arranged to bias the interface member into engagement with the body, in use, wherein the biasing member includes thermally insulating material so that the biasing member is configured to resist heat transfer away from the interface member.

22. The interface element of claim 21, wherein the substrate layer is disposed between a pair of conductive layers.

23. The interface element of claim 22, wherein the interface member includes thermal links extending between the conductive layers.

24. The interface element of claim 21, wherein the interface member includes a rigid substrate layer and a flexible substrate layer.

25. The interface element of claim 24, wherein the biasing member is formed from the same material as the flexible substrate layer of the interface member.

26. The interface element of claim 25, wherein the biasing member is continuous with the flexible substrate layer of the interface member.

27. The interface element of claim 21, wherein the or each conductive layer is divided into multiple thermally conductive regions separated by thermally insulating regions.

28. The interface element of claim 21, further comprising an electrically conductive path extending along the length of the biasing member and onto the interface member.

29. The interface element of claim 21, formed as a flexi-rigid printed circuit board.

30. The interface element of claim 21, further comprising a set of biasing members arranged around the interface member.

31. The interface element of claim 30, wherein the biasing members are of substantially equal length.

32. The interface element of claim 21, further comprising at least one axis of symmetry and/or at least one degree of rotational symmetry.

33. The interface element of claim 21, wherein thermally insulating material represents at least half of the volume of the or each biasing member.

34. The interface element of claim 33, wherein the or each biasing member is formed predominantly from thermally insulating material.

35. The interface element of claim 21, wherein the interface member includes an absorption layer that is configured to absorb photon energy to generate heat when the interface member is irradiated by a light source.

36. The thermal interface arrangement of claim 1, wherein the or each interface assembly is defined by the interface element of claim 21.

37. A heater system comprising the thermal interface arrangement of claim 1 or claim 36, and a heater arrangement configured to heat the interface member.

38. The heater system of claim 37, wherein the heater arrangement is integrated with the thermal interface arrangement.

39. The heater system of claim 37, wherein the heater arrangement includes a light source that is operable to direct radiation towards the interface member.

40. The heater system of claim 39, wherein the light source is mounted on the support structure of the thermal interface arrangement.

41. The heater system of claim 39, wherein the light source includes a light emitting diode.

42. The heater system of claim 39, wherein the light source is arranged to emit radiation in the ultraviolet and/or visible range.

43. The heater system of claim 37, wherein the heater arrangement includes a heater mounted on or integral with the interface member.

44. The heater system of claim 37, wherein the thermal interface arrangement includes multiple interface assemblies mounted on the support structure, each interface assembly including:
an interface member arranged to engage the body to form a thermal interface; and
a biasing member acting between the support structure and the interface member to bias the interface member away from the support structure and into engagement with the body, in use, wherein the biasing member includes thermally insulating material so that the biasing member is configured to resist heat transfer from the interface member to the support structure;
and wherein the heater arrangement is configured to heat each interface member.

45. The heater system of claim 44, wherein the heater arrangement is configured to heat each interface member independently.

46. A diagnostic device comprising the thermal interface arrangement of claim 1 or claim 36, the interface element of claim 21, or the heater system of claim 37.
